(19) United States
(12) Patent Application Publication
(10) Pub. No.: US 2008/0285456 A1
(43) Pub. Date: Nov. 20, 2008

(54) Method for Selective Load Compensation

(76) Inventor: Thomas Bahls, Greifswald (DE)

Correspondence Address: SIEMENS SCHWEIZ AG;I-47, INTELLECTUAL PROPERTY, ALBISRIEDERSTRASSE 245, ZURICH, CH-8047, CH

(21) Appl. No.: 11/628,902

(22) PCT Filed: May 21, 2005
(86) PCT No.: PCT/EP05/05535

§ 371 Date: Dec. 8, 2006

(51) Int. Cl. G01R 31/08

(52) U.S. Cl. 370/236

(57) ABSTRACT

A method for distributing a traffic load on several ports of a switch involves reading traffic information from the switch, and passing the read traffic information to a processor. The processor executes an algorithm that initiates a precise examination of criteria of the traffic information. The method includes further determining whether the results of the precise examination are comparable with a predetermined result. In the event of a negative result of this comparison, the information of the reference table is read and edited so that when the edited reference table is implemented the data load is redistributed so that the result of future examinations lies within the frame of the predetermined result. The edited reference table is forwarded to the switch for its actual implementation.

### BACKGROUND TO THE INVENTION

The invention relates to a method for selective load compensation in accordance with the preamble of Claim 1. More precisely, it refers to a method by means of which for its realization the necessary means is arranged outside a switch, with an effective dynamic load compensation taking place.

Switches of this kind such as Ethernet LAN (local area network) switches are known and are used as components of a packet-switched telecommunication network. These switches implement communication of the data packages between a number of network nodes that are based on a preset algorithm. The incoming data packets to the switch are temporarily stored in a buffer memory or register. The message header is read and an address for the data packet is specified. A reference table with addresses is consulted and a procedure is derived from this, in order to obtain the best possible connection between the switch and the destination network node of the data packet. A connection between two correspondingly long segments is indicated in order to forward the data packets from the switch, through the segments, to the network node. The usual Ethernet-based LAN uses an Ethernet frame that includes a normal data packet and also the charging information of the frame and a special message header that contains the MAC address information on the origin and destination of the packet. MAC addresses or media access control, are physical addresses of a device such as the NIC (network interface card) of a computer located in a network. The MAC address includes up to two long parts, each six bytes long. The first three bytes identify the company that has produced the NIC. The second three bytes are the serial number of the NIC itself. NIC stands for Network Interface Card that, as the name suggests, enables communication between the subscriber terminal and the network. NIC can equally refer to the Ethernet card.

The transmission of packet-switched data includes several known methods for forwarding the data packets. Each of them depends upon the internal hardware and software in the system. Such methods include cut-through, store and forward, and fragment-free transmission. For the cut-through, the switch reads the MAC address immediately a packet has been detected and begins with the cut-through or forwarding, directly after the six bytes have been stored, regardless of the remaining packets still being received or incoming. With store and forward, the complete data packet is stored in a memory, checked for errors and then forwarded on the basis of the succeeding read MAC address. If an error is detected during this process the data packet is discarded. It is known that some switches combine the cut-through, storage and forwarding process in a varying gradation. The “fragment-free transmission” method means the same as the cut-through, but with the difference that the first 64 bytes of the data packet are stored before forwarding takes place. The basis for this process is that most errors occur in the first 64 bytes, thus providing the opportunity for the switch to discover the errors early without having to suffer the delay due to the storage of more than the 64 bytes. Consequently, due to the operating mode, the switch collects certain basic information on the data packets to be forwarded, regardless of the type of initiation performed by the switch.

In order to additionally obtain information on the data packets, the switches are configured so that they set up their own reference table based on information learned or received from network nodes arranged in the network. Such learning is automatically initiated without there being a demand for switching from a network administrator. The setting up of a reference table is normally referred to as transparent bridging. Transparent bridging has five parts, i.e. learning, flooding, filtering, sending and altering. In short, learning is a process by means of which the switch when encountering a new MAC address simply adds the address with the respective network node to its own reference table. Flooding is a process by means of which the switch searches for a network node, the address of which is previously unknown to it and then supplies (floods) all the network segments known to it (except the receiving segment) with the data packet. Consequently, the suitable required recipient then acknowledges receipt of the packet. With this acknowledgement, the flooding switch now knows the two network nodes and their location and can thus establish a connection between them and transmit the data packet. In a case where the switch detects two network nodes and determines that they both have the same common network, the switch updates its own reference table, by means of which the part of the filter was described, and thus cannot interfere in the communication between the two sharing nodes. Altering is a form of cleansing the memory of the switch of addresses that have not been used within a specified time period. On the basis of the process already described, the reference table of the switch can be set up and the information on the network node connection is then available through the memory assigned in the switch.

Normally switches operate on the data connection or the second layer of the OSI reference model. Some switches that are similar to routers and are known as layer 3 switches operate on the third layer of the OSI reference model, i.e. on the network level. The applications that control the network run on the highest layer, the application layer. A general basis for the uses of the network control is the signaling network management protocol or the simple network management protocol (SNMP). Consequently, most of the devices controlled by the network are compatible with the SNMP. The applications of the network control question a control agent on this basis, using a supported management information base (MIB). The question is made through the SNMP. The MIB is a storage location for properties and parameters that are controlled by a device of the network, such as a switch. Therefore, the SNMP communicates via the MIB with the switch, obtains information from same and performs the control of the switch in a different manner. This information can include an error counter or data load etc. In addition, the API (Application Programming Interface) is software that is used to enable communication with the controlled switches of the network. Basically, the API is a set of standard software of data formats that use application programs in order to establish contact with the network services.

Detection of the data packets, specification or performance of hash functions and a logic specification of instructions to a network node (via a hash value) is performed by the hardware of the switch. The above method is based on internal (with regard to the switch) measures (hardware and software). As soon as these are implemented, switches remain relatively static and are predictable with regard to their operating mode. In other words, the switches do not behave dynamically with regard to the various data loads and their requirements. Therefore, certain ports of a switch can be subjected to a greater data load than other ports of the same switch. This poses the problem of the accumulation of data traffic at the switch, resulting in the switch being slower and therefore also a reduction in the communication between the respective network nodes and finally (to different degrees) also the performance of the complete network.

A known solution to this problem is the introduction of a certain flexibility in the hardware of the switches. This increased flexibility represents a change to a number of parameters and/or hash functions in order to achieve a more balanced load distribution. The change can be based on an analysis of the current data traffic situations and their requirements. Such a restructuring can be possible during ongoing operation. Up to now, the communication, that has already been assigned in a logical manner to a special port of the switch, cannot be diverted or redirected to a different port. Consequently a solution for reswitching or redistributing the data load is necessary, whereby the switch can function dynamically, with it being possible to divert or redistribute the data load regardless of the fact that the data loads have already been assigned. The solution must also be flexible in application so that it can also be applied to existing switches, thus increasing its capability without the need to replace the switches.

The object of this invention is to find a solution to this problem and the solution is given in the characterizing part of Claim 1. Embodiments are given in the dependent claims. The object of this invention is to provide a method whereby a processor external to the switch is provided in order to precisely examine the data load and determine whether the load advantageously resembles a desired distribution. If this is not the case, the reference table of the switch is read and revised, and then reswitched to active, so that after this operation has been performed the edited table diverts the data traffic to different ports, thus achieving an advantageous distribution result.

This invention is described with reference to drawings. The drawings are as follows:

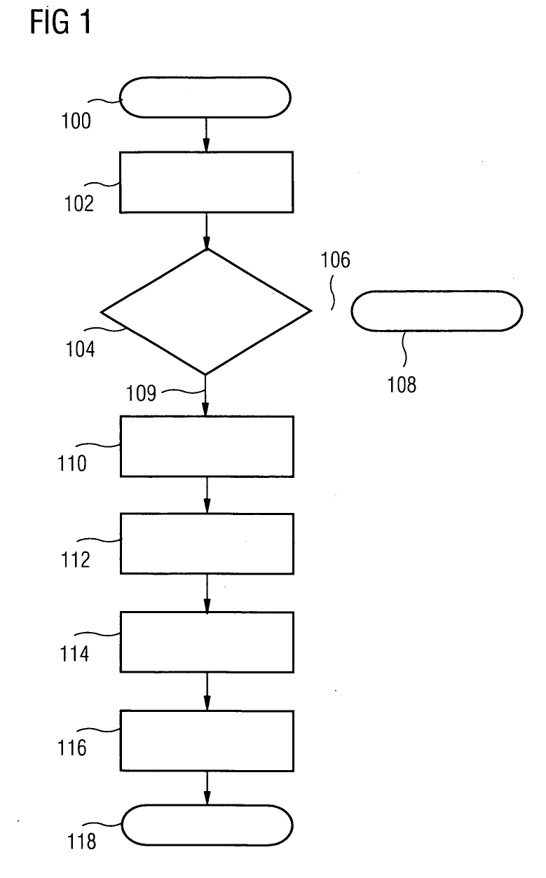

FIG. 1 A flow diagram of the method, and

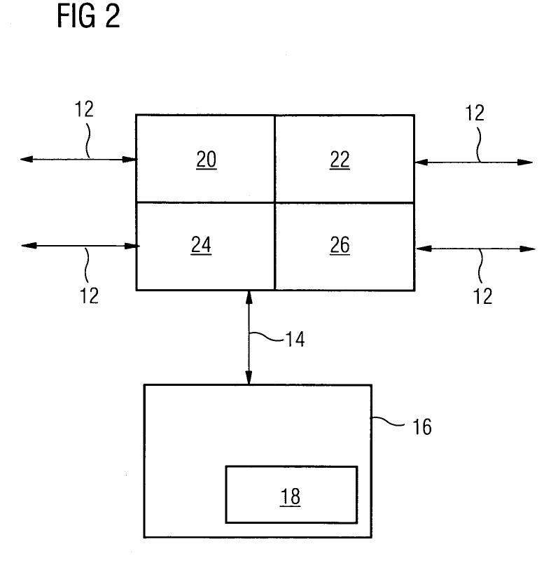

FIG. 2 A block diagram of a system for performing the presented method.

FIG. 1 shows a flow diagram with the steps that are carried out by the presented invention in order to achieve the required load compensation within a switch. The method begins as step 100 and continues to step 102, with the information on the data load being read from the switch. As is already known and explained above, the switches provide several sources and several different significant groups of information that are characteristic of the data load. The sources of information include SNMP, API, network support, network manager, switch memory etc. The information can in this case be as simple as counting the data packets that are routed via a special port or can just contain data from a network node or the data giving details with respect to the nature of the transmitted data packets. The data is read for one or more ports of the switch. After receiving the read load distribution of the data traffic, a comparison is made, in step 104, between the read load distribution and the desired load distribution and a determination is made as to whether the read load distribution advantageously agrees with the desired load distribution. The tolerance for this comparison is a matter for the configuration and application of the method. The presented method should, however, also not be limited to any type of data or data origin.

If the read data advantageously resembles the desired load distribution (step 106), the method returns to the start (step 108). If the read data does not, however, resemble the desired load distribution (step 110), the reference table is read and precisely examined (step 112). A determination is made as to how the reference table can be edited so that the data traffic currently being managed by the switch can be redistributed among the ports of the switch in order to achieve the desired distribution of the traffic load. Because this method is suitable for every type of desired load distribution for each type of switch that has ports provided with processors and means for data storage, the external processor and its programming capability must have a high degree of flexibility. The processor used and the programming are therefore a matter for the configuration. After editing, the reference table is sent back to the switch for implementation (step 116). After a predetermined time period, the process returns to the start (step 118) and the aforementioned steps are repeated.

FIG. 2 describes a block diagram with a system for the performance of the inventive method. As shown, a switch 10 has four components, i.e. a switch table 20, a hash function 22, a processor interface 24 and a register 26. The tasks of these individual components have already been described above. A brief description is repeated here. The switch table 20 indicates the port of the switch through which packets for a specific network node are forwarded. The hash function 22 is a processing of information according to specific criteria. The processor interface 24 enables communication with the processor 16 via a connection 14. The register 26 is a temporary memory used to receive, hold and transfer data. The processor 16 includes software 18 for processing algorithms. Numerous segments 12 enable communication with the switch 10, each with connection or subscriber interfaces. As used with this invention, the algorithms can be chosen so that their implementation results in the desired distribution of the data load. The configuration of algorithms is known to the person skilled in the art.

Whereas the algorithm in this case is used for a simple counting of packets, other criteria and implementations can also be envisaged. For example: comparison of the static hash operations of the switch; a last bit of the srcMAC that is zero or one, and a hash value at the port; the number per port of frames conveyed from the register; other functions of SNMP functions that provide detailed information on the traffic load situation, qualitatively separated from the pure number, such as for example sorting according to business customers, private customers, the amount of connecting interfaces etc.

Whereas this invention has been described in the aforementioned embodiment, it would be clear to the person skilled in the art that other embodiments can be found without departing from the core of this invention, such as embodiments without link aggregation and hash function in order to determine the load distribution to connection interfaces logically separated from each other.

### LIST OF REFERENCE CHARACTERS

10 Switch
12 Segment
14 Switch-processor connection
16 Processor
18 Software for processing algorithms
100 Start
102 Reading data
104 Requesting load compensation
106 Answer to request is “yes”
108 Return to start
109 Answer to request is “no”
110 Reading reference table
112 Editing reference table
114 Replacing the original reference table with the edited reference table
116 Return to start
118 End

1. A method for distributing a traffic load on several ports of a switch, comprising:
reading traffic information from the switch;
passing the read traffic information to a processor;
executing an algorithm by the processor, with the algorithm initiating a precise examination of criteria of the traffic information;
determining whether results of the precise examination are comparable with a predetermined result;
in the event of a negative result of this comparison, information of a reference table is read and edited so that when the edited reference table is implemented a data load is redistributed so that the result of future examinations lies within a frame of the predetermined result; and
forwarding the edited reference table to the switch for its actual implementation.

2. The method of claim 1, wherein one of the criteria of the traffic information is the number of data packets that are managed by at least one port of the switch.

3. The method of claim 1, wherein one of the criteria of the traffic information is the number of frames conveyed per port.

4. The method of claim 1, wherein one of the criteria of the traffic information are considerations of a service quality.

5. The method of claim 1, including:
examining the data load conveyed by the switch with at least an SNMP function and API; and
communicating the results of the examination to the processor for precise analysis by means of the algorithm.

6. The method of claim 1, including analyzing a register of the switch and communicating the results of the analysis to the processor for further analysis by means of the algorithm.

7. The method of claim 1, including periodically repeating the steps of reading the traffic information, determining whether the traffic load is balanced, the specification of a revised reference table for the switch and replacing the existing reference table by the revised reference table for a previously determined time period.
